(19) United States
(12) Patent Application Publication
(10) Pub. No.: US 2009/0017637 A1
(43) Pub. Date: Jan. 15, 2009

(54) METHOD AND APPARATUS FOR BATCH PROCESSING IN A VERTICAL REACTOR

(76) Inventors: Yi-Chiau Huang, Fremont, CA (US); Maitreyee Mahajani, Saratoga, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/775,761

(22) Filed: Jul. 10, 2007

(51) Int. Cl. H01L 21/469; C23C 16/00

(52) U.S. Cl. 438/758; 118/728; 257/E21.091

(57) ABSTRACT

The present invention generally provides an apparatus and method for the processing a plurality of substrates in a batch processing chamber. One embodiment of the present invention provides a method for processing a plurality of substrates comprising positioning the plurality of substrates in an inner volume of a batch processing chamber, wherein the plurality of substrates are arranged in a substantially parallel manner, and at least a portion of the plurality of substrates are positioned with a device side facing downward, and flowing one or more processing gases cross the plurality of substrates.

### BACKGROUND OF THE INVENTION

1. Field of the Invention

Embodiments of the present invention generally relate to batch processing of semiconductor substrates. More particularly, embodiments of the invention relate to methods and apparatus for efficient and uniform delivery of one or more processing gases in a batch processing reactor.

2. Description of the Related Art

The term batch processing generally refers to the processing of two or more substrates at the same time in one reactor. There are several advantages to batch processing of substrates. Batch processing can increase the throughput of a substrate processing system by performing a process recipe step that is disproportionately long compared to other process recipe steps in a substrate processing sequence. The use of batch processing for the longer recipe step effectively decreases the processing time per substrate. Another advantage of batch processing may be realized in some processing steps where expensive precursor materials are used, such as ALD and CVD, by greatly reducing the usage of precursor gases per substrate as compared to single substrate processing. The use of batch processing reactors may also result in smaller system footprints as compared to cluster tools which include multiple single substrate processing reactors.

Two advantages of batch processing, which may be summarized as increased throughput and reduced processing cost per substrate, directly affect two related and important factors which are device yield and cost of ownership (COO). These factors are important since they directly affect the cost to produce an electronic device and thus a device manufacturer's competitiveness in the market place. Batch processing is, therefore, often desirable since it can be effective in increasing device yield and decreasing COO.

A state of the art batch processing reactor generally includes a processing chamber defining an inner volume. During processing, a plurality of substrates are generally disposed within the inner volume, usually supported by a batch substrate support, such as a substrate boat. One or more processing gases, such as precursors, carrier gases, heating/cooling gases, and purge gases, are typically delivered to the entire inner volume during a batch processing. Even though most processing gases, particularly the precursors, are intended to process only a device side of each substrate during processing, the processing gases generally fill the entire inner volume of the processing chamber and process all the exposed surfaces of a substrate, such as the device side, the back side and the bevel edge. The unintended processing on the back side and bevel edge of a substrate sometimes generates unwanted deposition which requires extra step to remove. Reducing spacing between substrates can reduce processing volume is adapted to reduce production cost. However, the reduced spacing between substrates causes within-substrate uniformity to decrease since reduced spacing makes it harder to generate uniform gas flow across a substrate.

Furthermore, the unintended processing on the back side and bevel edge consumes extra processing gases, which increases the cost of ownership, particularly in situations where the processing gases -are expensive. Additionally, undesired particles may generate during processing and land on the device side of the substrate causing particle contamination.

Therefore, there is a need for a batch processing chamber that can provide efficient and uniform processing gas delivery, and reduced particle contamination.

### SUMMARY OF THE INVENTION

Embodiments of the present invention generally provides an apparatus and method for the processing a plurality of substrates in a batch processing chamber.

One embodiment provides a method for processing a plurality of substrates comprising positioning the plurality of substrates in an inner volume of a batch processing chamber, wherein the plurality of substrates are arranged in a substantially parallel manner, and at least a portion of the plurality of substrates are positioned with a device side facing downward, and flowing one or more processing gases cross the plurality of substrates.

Another embodiment provides a method for processing semiconductor substrates comprising loading a plurality of substrates on a substrate support assembly configured to support the plurality of substrates in a substantially parallel manner, wherein a device side of each of the plurality of substrates is oriented to face a device side of a neighboring substrate, positioning the substrate assembly in a processing volume defined by a batch processing chamber, and flowing one or more processing gases to the processing volume.

Yet another embodiment provides a batch processing chamber comprising a chamber body defining a processing volume, and a substrate support assembly comprises three or more supporting posts, and a plurality of supporting fingers extending from the three or more supporting posts, wherein the plurality of supporting fingers form a plurality of slots configured to support a plurality of substrates therein, and at least a portion of the plurality of supporting fingers have a sloping surface configured to receive a substrate.

### BRIEF DESCRIPTION OF THE DRAWINGS

So that the manner in which the above recited features of the present invention can be understood in detail, a more particular description of the embodiments, briefly summarized above, may be had by reference to embodiments, described below and referred in the appended drawings. It is to be noted, however, that the appended drawings illustrate only typical embodiments of this invention and are therefore not to be considered limiting of its scope, for the invention may admit to other equally effective embodiments.

FIG. 1A schematically illustrates a cross-sectional side view of a batch processing chamber in accordance with one embodiment of the present invention.

FIG. 1B schematically illustrates a sectional top view of the batch processing chamber of FIG. 1A.

FIG. 2 schematically illustrates a partial cross-sectional side view of a batch processing chamber in accordance with one embodiment of the present invention.

FIG. 3A schematically illustrates a sectional top view of a substrate boat in accordance with one embodiment of the present invention.

FIG. 3B schematically illustrates a side view of one embodiment of a support post used in a substrate boat of the present invention.

FIG. 3C schematically illustrates a side view of another embodiment of a support post used in a substrate boat of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally provides methods and apparatus for a batch processing chamber that can provide uniform and efficient gas delivery to a plurality of substrates disposed in the batch processing chamber.

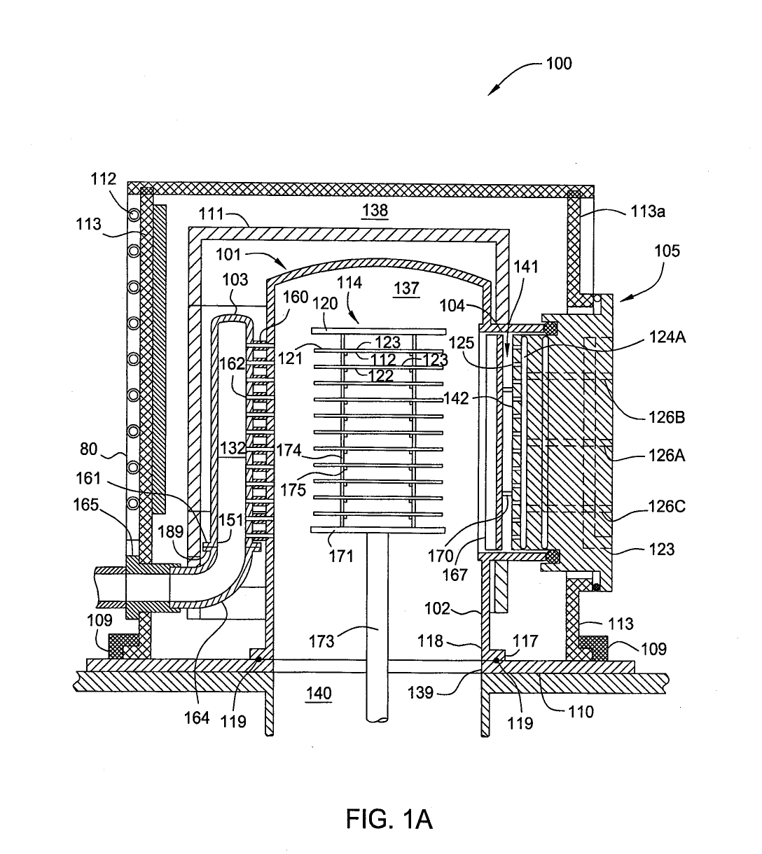

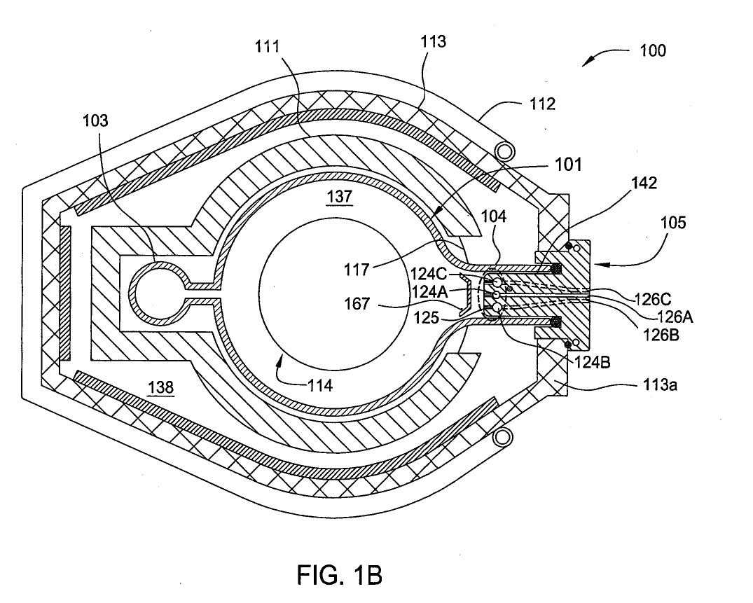

FIG. 1A schematically illustrates a cross-sectional side view of a batch processing chamber 100 in accordance with one embodiment of the present invention. FIG. 1B schematically illustrates a sectional top view of the batch processing chamber 100 of FIG. 1A. The batch processing chamber 100 comprises an outer chamber 113 which may be covered with one or more panels 80 having cooling conduits 112 that are in contact with an exterior surface of the outer chamber 113. The outer chamber 113 may be made of any suitable high temperature materials, such as stainless steel, nickel-plated aluminum, ceramic, and quartz.

The batch processing chamber 100 further comprises a quartz chamber 101 defining and enclosing a processing volume 137 and configured to accommodate a batch of substrates 121 stacked in a substrate boat 114. A heater block 111 is disposed in an outer volume 138 between the outer chamber 113 and the quartz chamber 101. The heater block 111 is configured to heat the substrates 121 inside the processing volume 137.

The quartz chamber 101 generally comprises a chamber body 102 having a bottom opening 118, an inject pocket 104 formed on one side of the chamber body 102, an exhaust manifold 103 connected to the chamber body 102 on an opposite side of the inject pocket 104, and a flange 117 formed adjacent to the bottom opening 118. The inject pocket 104 may be welded in place of slots milled on the chamber body 102. The inject pocket 104 has the shape of a flattened quartz tube with one end welded onto the chamber body 102 and one end open. The exhaust manifold 103 may have the shape of a tube, and may be connected to the chamber body 102 by one or more connecting conduits 160 that are welded or fused between the chamber body 102 and exhaust manifold 103. In one embodiment, the one or more connecting conduits 160 are configured to limit fluid communication between the processing volume 137 and an exhaust volume 132 of the exhaust manifold 103. The exhaust manifold 103 has an exhaust manifold port 151 where an exhaust manifold flange 161 may be coupled to the exhaust manifold 103.

The inject pocket 104 welded on a side of the chamber body 102 defines an inject volume 141 in communication with the processing volume 137. The inject volume 141 generally covers an entire height of the substrate boat 114 when the substrate boat 114 is in a process position such that an inject assembly 105 disposed in the inject pocket 104 may provide a horizontal flow of processing gases to every substrate 121 in the substrate boat 114.

In one embodiment, the inject assembly 105 is disposed along a side wall 113a of the outer chamber 113 and partially inside the inject pocket 104 of the quartz chamber 101. The inject assembly 105 is configured to be introduced processing gases into the processing volume 137. The inject assembly 105 has one or more gas inlet channels 126A, 126B, 126C, each configured to connect a gas source. The gas inlet channels 126A, 126B, 126C may be milled horizontally across the inject assembly 105. Each of the gas inlet channels 126A, 126B, 126C opens to a vertical channel 124A, 124B, 124C respectively. The vertical channels 124A, 124B, 124C are connected to the processing volume 137. The process gas comes from the gas inject channels 126A, 126B, 126C flows into the processing volume 137 horizontally through a plurality of horizontal holes 125 formed in a front panel 142 of the inject assembly 105. Each of the vertical channels 124A, 124B, 124C is configured to supply the processing volume 137 with a process gas independently, and each vertical channels 124A, 124B, 124C may supply a different process gas.

The plurality of horizontal holes 125 may be formed to enhance the uniformity of process gas flow over the surfaces of the substrates 121 disposed in the substrate boat 114. In one embodiment, the plurality of horizontal holes 125 may be distributed corresponding to the distribution of substrates 121 in the substrate boat 114. For example, each of the plurality of horizontal holes 125 may direct the processing gas to flow horizontally and substantially parallel to a substrate. The substrate boat 114 may also rotate during substrate processing to further enhance process gas flow uniformity over the substrates 121.

A diffuser plate 167 may be coupled to the inject assembly 105 using one or more connectors 170. In one embodiment, the diffuser plate 167 may be suitably coupled to the inject assembly 105 so that both may be removed as a unit from the outer chamber 113. The diffuser plate 167 may be disposed near horizontal holes 125 so that the flow of process gas over the substrate 121 surface is more uniform. The diffuser plate 167 diverts the gas flow into two streams towards the substrate 121 periphery and away from substrate edge closest to the diffuser plate 167. Detailed description of diffuser plates may be found in U.S. patent application Ser. No. 11/381,966, entitled “Batch Processing Chamber with Diffuser Plate and Injector Assembly”, and filed May 5, 2006, which is hereby incorporated by reference in its entirety.

Referring to FIG. 1A, the quartz chamber 101 and the outer chamber 113 are supported by a chamber support plate 110. The outer chamber 113 has a flange 109 which is connected to the support plate 110. In one embodiment, the chamber support plate 110 is made of anodized aluminum. In another embodiment, the chamber support plate 110 may be made of nickel-plated stainless steel. The flange 117 of the quartz chamber 101 may be welded on around the bottom opening 118 and is configured to facilitate a vacuum seal for the chamber body 102. The flange 117 is generally in intimate contact with the support plate 110 which has aperture 139. The bottom opening 118 aligns with the aperture 139. An O-ring seal 119 may be disposed between the flange 117 and the support plate 110 to seal the processing volume 137 from the outer volume 138 defined by the outer chamber 113, the support plate 110 and the quartz chamber 101. An O-ring (not shown) may be disposed between a flange 109 and the support plate 110 to seal the outer volume 138 from the exterior environment. Other O-ring seals (not shown) may be disposed between an exhaust manifold flange 161 and-an elbow flange 189, between a collar connector 165 and an elbow conduit 164, and elsewhere to isolate the processing volume 137 from the outer volume 138. The support plate 110 may be further connected to a load lock 140 where the substrate boat 114 may be loaded and unloaded. The substrate boat 114 may be vertically translated between the processing volume 137 and the load lock 140 via the aperture 139 and the bottom opening 118.

Batch processing chambers are further described in U.S. patent application Ser. No. 11/249,555 entitled “Reaction Chamber with Opposing Pockets for Gas Injection and Exhaust”, and filed Oct. 13, 2005, and which is hereby incorporated by reference.

The batch processing chamber 100 of the present invention may be used to perform a plurality of processes, such as for example, chemical vapor deposition (CVD), atomic layer deposition (ALD),

Substrates being processed in a batch processing chamber are generally transported in and out the batch processing chamber and supported during processing by a batch substrate support, such as a cassette, or a substrate boat. A batch substrate support, such as a substrate boat, generally has a plurality of substrate supporting slots configured to support a plurality of substrates in a manner such that a device side of each of the plurality of substrates is exposed to a processing environment, i.e. the processing gases.

The substrate boat 114 of the present invention generally comprises a bottom plate 171 connected to a top plate 120 by three or more supporting posts 174. A plurality of supporting fingers 175 extend from each of the supporting posts 174. The supporting fingers 175 from the three or more supporting posts 174 define a plurality of slots, each configured to support a substrate 121 thereon. In one embodiment, the substrate boat 114 is configured to position the plurality of substrates 121 in a substantially parallel manner with an even or variable interval between neighboring substrates 121.

The substrate boat 114 is coupled to a shaft 173 which is connected to an actuation mechanism. The shaft 173 moves up and down to transfer the substrate boat 114 along with substrates disposed therein in and out the processing volume 137. The plurality of substrates 121 may be loaded onto the substrate boat 114 when the substrate boat is lowered in the load lock 140. The substrate boat 114 is then raised into the processing volume 137 which is then sealed from the load lock 140. One or more processing gases are then flown into the processing volume 137 according to the process recipe. After processing, the plurality of substrates 121 are lowered back into the load lock 140, unloaded for sub-sequential process steps.

A semiconductor substrate generally has a device side opposing a back side. The device side is where structures are built layer by layer to form electronic devices. The majority of semiconductor processing is performed to the device side of a substrate. The plurality of substrates 121 are arranged in the substrate boat 114 so that a device side of each substrate 121 is exposed to processing gases flowing in the processing volume 137 during processing.

During processing, the plurality of substrates 121 are disposed within the processing volume 137. One or more processing gases are flown into the processing volume 137 from the plurality of horizontal holes 125 of the inject assembly 105. A vacuum pump is usually connected to the exhaust manifold 103 forcing the one or more processing gases to exit the processing volume 137 through the connecting conduits 162 in the exhaust manifold 103, thus forming gas flow substantially parallel to the plurality of substrates 121. Such a gas flow in the processing volume 137 reduces particle contamination and improves process uniformity across the device side of each substrate and uniformity among the plurality of substrates 121.

Embodiments comprise positioning at least a portion of a plurality of substrates being processed with a device side facing down to reduce particle contamination, and/or increase process uniformity, and/or reduces processing volume.

In one embodiment, a plurality of substrates being processed are positioned in a device side down position in a vertical batch processing chamber to reduce particle contamination, wherein the vertical batch processing chamber refers to a batch processing chamber configured to process a plurality of substrates vertically stacked together, such as the batch processing chamber 100 of FIG. 1A.

In one embodiment, a plurality of substrates being processed are positioned in variable interval with variable device side orientation to increase substrate load, reduce processing volume and improve process uniformity. In one embodiment of the present invention, selective or alternative substrates in a plurality of substrates being processed are positioned in a device side down orientation in a vertical batch processing chamber.

In one embodiment, a plurality of substrates are positioned parallel with alternative device side orientation, such that a device side of a substrate is facing a device side of a neighboring substrate, and a back side of the substrate is facing a back side of another neighboring substrate. In one embodiment, the distances between the device sides of neighboring substrates are increased to improve uniformity and the distance between the back sides of two neighboring substrates are minimized to reduce processing volume. The plurality of substrates may be positioned horizontally with device sides alternatively facing up or down and intervals between substrates varied. The plurality of substrates may be positioned in any desired angle, for example vertical, with device sides alternatively facing one side or another, and intervals between substrates varied.

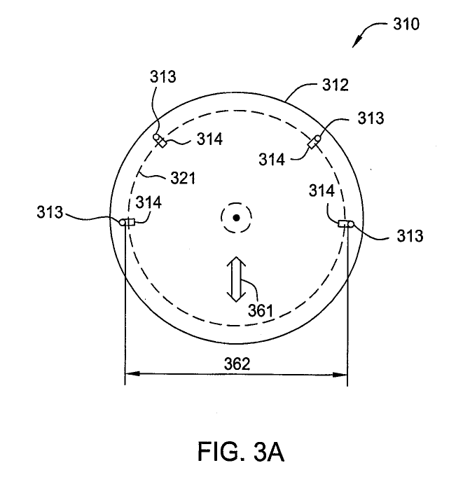

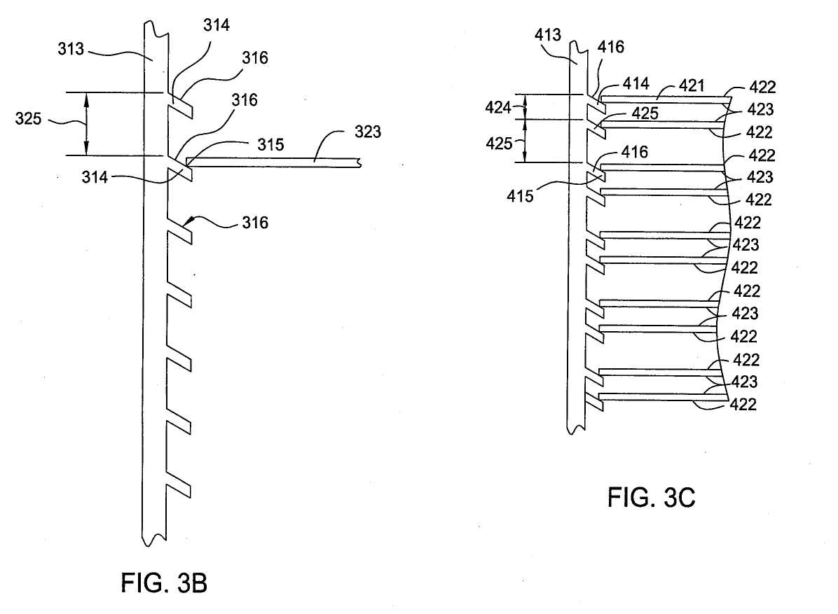

As shown in FIG. 1A, in one embodiment of the present invention, each of the plurality of substrates 121 is positioned in the processing volume 137 with a device side 122 facing down and a back side 123 facing up. Compared to a conventional device side facing up arrangement, this configuration greatly reduces particle contamination since particles generated during processing are less likely to land on the downward facing device sides 122 due to gravity, therefore, improving quality of devices built on the substrates 121. In one embodiment, the plurality of substrates 121 are arranged with equal intervals. The even distribution of substrates 121 ensures inter-substrate uniformity. In one embodiment, the supporting fingers 175 are configured to provide minimal contact to the substrates 121 to reduce generation of undesired particles. Embodiments of the supporting fingers are further described in FIG. 3A.

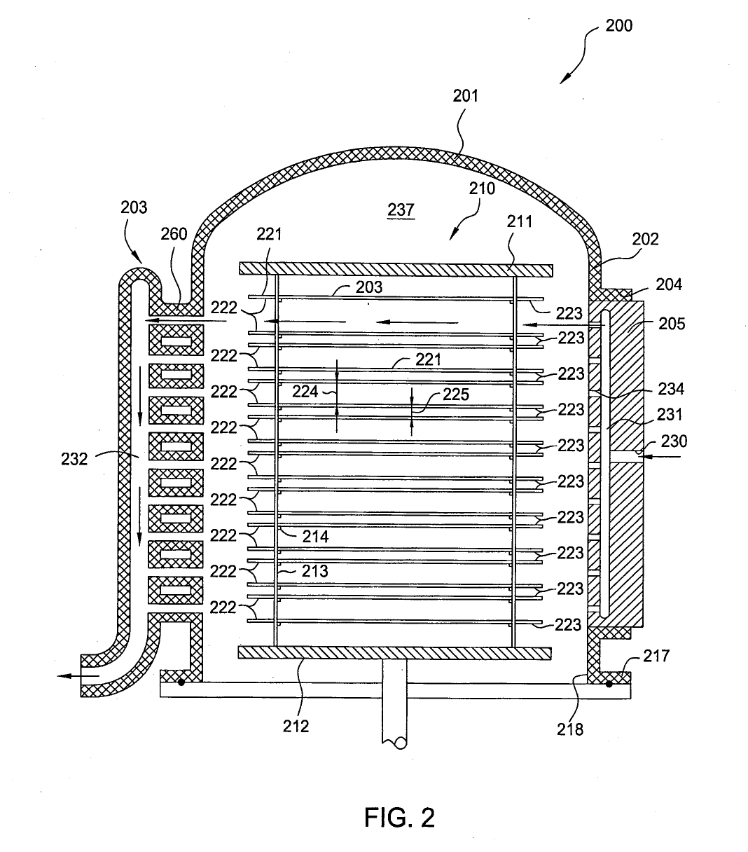

FIG. 2 schematically illustrates a partial cross-sectional side view of a batch processing chamber 200 in accordance with one embodiment of the present invention.

The batch processing chamber 200 comprises a quartz chamber 201. The quartz chamber 201 provides a processing volume 237 for a batch processing conducted in a controlled environment, for example in a low pressure, and/or elevated temperature. The quartz chamber 201 comprises a chamber body 202 having a bottom opening 218, an inject pocket 204 formed on one side of the chamber body 202, an exhaust manifold 203 connected to the chamber body 202 on an opposite side of the inject pocket 204, and a flange 217 formed adjacent to the bottom opening 218. The inject pocket 204 may be welded in place of slots milled on the chamber body 202. The inject pocket 204 has the shape of a flattened quartz tube with one end welded onto the chamber body 202 and one end open. The exhaust manifold 203 may have the shape of a tube, and may be connected to the chamber body 202 by one or more connecting conduits 260 that are welded or fused between the chamber body 202 and the exhaust manifold 203. In one embodiment, the one or more connecting conduits 260 are configured to limit fluid communication between the process volume 237 and an exhaust volume 232 of the exhaust manifold 203.

An inject assembly 205 is disposed in the inject pocket 204 to provide a horizontal flow of processing gases to the processing volume 237. The inject assembly 205 has one or more gas inlet channels 230 configured to connect to one or more gas sources. The one or more gas inlet channels 230 may be milled horizontally across the inject assembly 205 and connected to a vertical channel 231 which is further connected to the processing volume 237 via a plurality of horizontal holes 234 formed in the inject assembly 205. In one embodiment, each of the plurality of horizontal holes 234 may be positioned in a substantially equal elevation to a corresponding connecting conduit 260 to generate substantially horizontal gas flow across the processing volume 237.

A plurality of substrates 221 may be transferred in and out the processing volume 237 and supported by a substrate support assembly 210. The substrate support assembly 210 generally comprises a bottom plate 212 connected to a top plate 211 by three or more supporting posts 213. A plurality of supporting fingers 214 extend from each of the supporting posts 213. The supporting fingers 214 from the three or more supporting posts 213 define a plurality of slots, each configured to support a substrate 221 thereon. In one embodiment, the substrate support assembly 210 is configured to position the plurality of substrates 221 in a substantially parallel manner with variable intervals between neighboring substrates 221.

As shown in FIG. 2, the plurality of substrates 221 are positioned with alternative orientations. Every other one of the plurality of substrates 221 are positioned with a device side 222 facing down, and every other of one of the plurality of substrates 221 are positioned with a back side 223 down. Thus, any one the plurality of substrates 221 has the device side 222 facing the device side 222 of its neighboring substrate if there is a neighbor substrate on the device side 222, and has the back side 223 facing the back side 223 of its neighbor substrate if there in a neighbor on the back side 223. Two neighboring substrates 221 with device sides facing each other are positioned with a device side interval 224. Two neighboring substrates 221 with back sides facing each other are positioned with a back side interval 225.

In one embodiment, the back side interval 225 is compressed to be shorter than the device side interval 224 to increase substrate load with in the processing volume 237 without negative effects to within-substrate uniformity since in device side interval 224 dose not change. In one embodiment, the device side interval 224 and/or the back side intervals 225 are configured to be even across the substrate support assembly 210 to achieve inter-substrate uniformity.

There are several advantages for arranging substrates in a batch processing chamber in alternative orientations with alternative intervals. First, the arrangement increases substrate load in the processing chamber, reducing processing volume occupied by each substrate, therefore, reducing cost. Second, the arrangement reduces particle contamination. For example, nearly half of the substrates are positioned device side down, therefore, provide less opportunity of particles to land on a device side. Third, back sides of the substrates are exposed to less processing gas, thus, reducing unwanted deposition on the back sides.

In one embodiment, the plurality of horizontal holes 234 in the inject assembly 205 may be arranged in an interval equal to summation of the device side interval 224, the back side interval 225 and two substrate thicknesses to provide a substantially horizontal gas flow across each device side intervals 224. Additionally, the connecting conduits 260, which connect the processing volume 237 to the exhaust volume 232, may be arranged in the same intervals as the plurality of horizontal holes 234 in the inject assembly 205.

FIG. 3A schematically illustrates a sectional top view of a substrate boat 310 in accordance with one embodiment of the present invention. The substrate boat 310 is configured to provide support to a plurality of substrates with reduced contact areas, which is suitable for holding a substrate on a device side. The substrate boat 310 has similar structure as the substrate boat 114 of FIG. 1 and the substrate support assembly 210 of FIG. 2. The substrate boat 310 is configured to transport and support a plurality of substrates thereon. The substrate boat 310 generally comprises three or more supporting posts 313 extending from a bottom plate 312. In another embodiment, the three or more supporting posts 313 may be coupled to a top plate, not shown, for a sturdy structure. Each of the supporting posts 313 having a plurality of supporting fingers 314 extending therefrom. A plurality of substrate supporting slots are formed by the plurality of supporting fingers 314 configured to provide support to a substrate near an edge 321. Each supporting slots comprises one supporting finger 314 from each of the three or more supporting posts 313.

As shown in FIG. 3A, in one embodiment, the substrate boat 310 comprises four supporting posts 313 and a substrate is configured to be supported at four locations near the edge 321. The four supporting posts 313 are arranged such that a distance 362 between two supporting posts 313 are greater than a diameter of a substrate, thus, a substrate may be loaded and unloaded along direction 361.

FIG. 3B schematically illustrates a side view of one embodiment of the supporting post 313 of the substrate boat 310 of FIG. 3A. The supporting fingers 314 extend from the supporting posts 313 at an even interval 325. Each supporting finger 314 has a top surface 316 configured to receive a substrate 323. The top surface 316 is sloping downwardly so that the top surface 316 maintains a point contact to the substrate 323 at point 315. The point support mechanism reduces contact between the substrates and the substrate boat 310, hence, reducing particle generation from contact and avoiding damaging device side of the substrates.

In one embodiment, the interval 325 may be configured to meet the spacing requirement for within-substrate uniformity for device face up or device face down processing. In another embodiment, the interval 325 may be configured to be the shortest distance allowed by the system limitation, such as a robot limitation. In an alternative orientation arrangement described above, the back side interval between two neighboring substrates may be close to the interval 325 minus the thickness of the substrate, while the device side interval between two neighboring substrates may be two or more interval 325 minus the thickness of the substrate.

In one embodiment, the supporting posts 313 and supporting fingers 314 may be made from high temperature and chemical resistive material, such as quartz and ceramic.

FIG. 3C schematically illustrates a side view of another embodiment of a support post 413 which may be used in a substrate boat of the present invention, such as the substrate boat 310 of FIG. 3A. A plurality of supporting fingers 414 extend from the supporting posts 313 with alternative intervals. Each supporting finger 414 has a top surface 416 configured to receive a substrate 421. The top surface 416 is sloping downwardly so that the top surface 416 maintains a point contact to the substrate 421 at point 415. The point support mechanism reduces contact between the substrates and the supporting fingers 414, hence, reducing particle generation from contact and avoiding damaging device side of the substrates.

As shown in FIG. 3C, the supporting fingers 414 are grouped in pairs, with each pair having a short interval 424 and neighboring pairs having a long interval 425. The uneven intervals are configured to satisfy the alternative orientation arrangement described above. Each pair of supporting fingers 414 are configured to support a pair of substrate 421 with back sides 423 facing each other and device sides 422 facing outwards.

In one embodiment, the short interval 424 in the alternative orientation arrangement of the present invention may be shorter than a robot limitation, which indicates a minimal space needed for a robot blade to pick up or drop a substrate without interfering with neighboring substrates, using a compressed substrate boat with two substrate boats movably connected to one another. Detailed description of embodiments of substrate boats may be found in U.S. patent application Ser. No. 11/216,969, filed Aug. 31, 2005, published Mar. 15, 2007 as United States Patent Publication 2007/0059128, entitled “Batch Deposition Tool and Compressed Boat”, which is hereby incorporated by reference.

In another embodiment, the short interval in the alternative orientation arrangement of the present invention may be reduced to be shorter than the robot limitation by loading/unloading the plurality of substrates in a certain order. For example, load substrates with device side facing up first, and then load substrates with device side facing down, or load substrates with device side facing down first, and then load substrate with device side facing up.

Even though a vertical batch processing chamber is described in accordance with the present application, the present invention is contemplated to be used in batch processing chambers in any suitable orientations.

While the foregoing is directed to embodiments of the present invention, other and further embodiments of the invention may be devised without departing from the basic scope thereof, and the scope thereof is determined by the claims that follow.

What is claimed is:

1. A method for processing a plurality of substrates, comprising:
positioning the plurality of substrates in an inner volume of a batch processing chamber, wherein the plurality of substrates are arranged in a substantially parallel manner, and at least a portion of the plurality of substrates are positioned with a device side facing downward; and
flowing one or more processing gases cross the plurality of substrates.

2. The method of claim 1, wherein positioning the plurality of substrates comprises orienting each of the plurality of substrates in a device side facing downward.

3. The method of claim 1, wherein positioning the plurality of substrates comprises alternating orientation of the device side of the plurality of substrates.

4. The method of claim 3, wherein positioning the plurality of substrates further comprises alternating interval of the plurality of substrates, wherein intervals between two neighboring substrates with device sides facing one another are larger than intervals between two neighboring substrates with back sides facing one another.

5. The method of claim 3, wherein positioning the plurality of substrates comprising reducing intervals between two neighboring substrates with back sides facing one another to increase substrate load in the batch processing chamber.

6. The method of claim 1, wherein positioning the plurality of substrates comprises loading the plurality of substrates in a substrate support assembly; and moving the substrate support assembly into the inner volume of the batch processing chamber.

7. The method of claim 6, wherein the substrate support assembly is configured to receive the plurality of substrates in a plurality of supporting slots, each of the plurality of supporting slots comprising three or more supporting fingers having downward sloping receiving surfaces.

8. The method of claim 1, wherein flowing one or more processing gases comprises flowing the one or more processing gases substantially parallel to the plurality of substrates.

9. A method for processing semiconductor substrates, comprising:
loading a plurality of substrates on a substrate support assembly configured to support the plurality of substrates in a substantially parallel manner, wherein a device side of each of the plurality of substrates is oriented to face a device side of a neighboring substrate;
positioning the substrate assembly in a processing volume defined by a batch processing chamber; and
flowing one or more processing gases to the processing volume.

10. The method of claim 9, wherein the plurality of substrates are positioned substantially parallel to a horizontal direction.

11. The method of claim 9, wherein spacing between the plurality of substrates is variable.

12. The method of claim 11, wherein intervals between two neighboring substrates with device sides facing one another are larger than intervals between two neighboring substrate with back sides facing one another.

13. The method of claim 9, wherein the substrate support assembly has a plurality of substrate supporting slots each configured to receive a substrate in a substantially horizontal orientation.

14. The method of claim 13, wherein each of the plurality of supporting slots comprising three or more supporting fingers having downward sloping receiving surfaces configured to receive a substrate near an edge of the substrate.

15. The method of claim 9, wherein flowing one or more processing gases comprises flowing the one or more processing gases substantially parallel to the plurality of substrates.

16. A batch processing chamber comprising:
a chamber body defining a processing volume; and
a substrate support assembly comprises:
three or more supporting posts; and
a plurality of supporting fingers extending from the three or more supporting posts, wherein the plurality of supporting fingers form a plurality of slots configured to support a plurality of substrates therein, and at least a portion of the plurality of supporting fingers have a sloping surface configured to receive a substrate.

17. The batch processing chamber of claim 16, wherein at least a portion of the plurality of slots are configured to receive a substrate with a device side facing down.

18. The batch processing chamber of claim 16, wherein the plurality of supporting fingers are evenly distributed along each of the three or more supporting posts.

19. The batch processing chamber of claim 16, wherein the plurality of supporting fingers are distributed in alternative intervals along each of the three or more'supporting posts.

20. The batch processing chamber of claim 16, further comprising:
an inject assembly coupled to one side of the chamber body configured to provide one or more processing gas to processing volume; and
an exhaust assembly coupled to the chamber body on a side opposite the inject assembly.
